(19) United States
(12) Patent Application Publication
(10) Pub. No.: US 2024/0160386 A1
(43) Pub. Date: May 16, 2024

(54) VARIABLE DENSITY STORAGE DEVICE

(71) Applicant: Micron Technology, Inc., Boise, ID (US)

(72) Inventors: Christopher Joseph Bueb, Folsom, CA (US); Aravind Ramamoorthy, Rocklin, CA (US); Anand Mudlapur, Folsom, CA (US); Zheng Wang, Louisville, CO (US); Olivier Duval, Pacifica, CA (US)

(21) Appl. No.: 18/492,569

(22) Filed: Oct. 23, 2023

Related U.S. Application Data
(60) Provisional application No. 63/425,599, filed on Nov. 15, 2022.

(51) Int. Cl. G06F 3/06

(52) U.S. Cl. CPC G06F 3/0659; G06F 3/0619; G06F 3/0632; G06F 3/0679

(57) ABSTRACT

Methods, systems, and devices for variable density storage device are described. A memory system may receive a write command to write data to the memory system. The memory system may write the data to a first set of memory cells of the memory system using a first write operation based on receiving the write command. The first set of memory cells store three or fewer bits of information in a single memory cell. The memory system may identify whether to transfer the data to a second set of memory cells on one or more parameters associated with the data. The second set of memory cells may store more bits of information in a single memory cell than the first set of memory cells. The memory system may transfer the data to the second set of memory cells based on identifying that the data is to be transferred.

### CROSS-REFERENCES

The present Application for Patent claims the benefit of U.S. Provisional Patent Application No. 63/425,599 by Bueb et al., entitled “VARIABLE DENSITY STORAGE DEVICE,” filed Nov. 15, 2022, assigned to the assignee hereof, and which is hereby incorporated by reference in its entirety.

### FIELD OF TECHNOLOGY

The following relates to one or more systems for memory, including variable density storage device.

### BACKGROUND

Memory devices are widely used to store information in various electronic devices such as computers, user devices, wireless communication devices, cameras, digital displays, and the like. Information is stored by programming memory cells within a memory device to various states. For example, binary memory cells may be programmed to one of two supported states, often corresponding to a logic 1 or a logic 0. In some examples, a single memory cell may support more than two possible states, any one of which may be stored by the memory cell. To access information stored by a memory device, a component may read (e.g., sense, detect, retrieve, identify, determine, evaluate) the state of one or more memory cells within the memory device. To store information, a component may write (e.g., program, set, assign) one or more memory cells within the memory device to corresponding states.

Various types of memory devices exist, including magnetic hard disks, random access memory (RAM), read-only memory (ROM), dynamic RAM (DRAM), synchronous dynamic RAM (SDRAM), static RAM (SRAM), ferroelectric RAM (FeRAM), magnetic RAM (MRAM), resistive RAM (RRAM), flash memory, phase change memory (PCM), 3-dimensional cross-point memory (3D cross point), not-or (NOR) and not-and (NAND) memory devices, and others. Memory devices may be described in terms of volatile configurations or non-volatile configurations. Volatile memory cells (e.g., DRAM) may lose their programmed states over time unless they are periodically refreshed by an external power source. Non-volatile memory cells (e.g., NAND) may maintain their programmed states for extended periods of time even in the absence of an external power source.

### BRIEF DESCRIPTION OF THE DRAWINGS

FIG. 1 illustrates an example of a system that supports variable density storage device in accordance with examples as disclosed herein.

FIG. 2 illustrates an example of a system that supports variable density storage device in accordance with examples as disclosed herein.

FIG. 3 illustrates an example of a storage capacity diagram that supports variable density storage device in accordance with examples as disclosed herein.

FIG. 4 illustrates an example of a process flow that supports variable density storage device in accordance with examples as disclosed herein.

FIG. 5 shows a block diagram of a memory system that supports variable density storage device in accordance with examples as disclosed herein.

FIG. 6 shows a flowchart illustrating a method or methods that support variable density storage device in accordance with examples as disclosed herein.

### DETAILED DESCRIPTION

Some memory systems may include multiple memory devices along with a memory system controller configured to manage the multiple memory devices. For example, a system that includes multiple not-and (NAND) memory devices (e.g., dies including NAND memory cells, which may be referred to as NAND dies) and a memory system controller may be referred to as a managed NAND (mNAND) system. In some cases, the memory system controller may be configured to exchange signaling with a host system for the memory devices and exchange related signaling with the memory devices. For example, the host system may send commands to the memory system controller (e.g., read or write commands). Thus, the memory devices may perform, in response to the commands issued by the memory system controller, various operations to satisfy the corresponding host-issued commands (e.g., reading and writing data).

In some examples, a memory system may write data to one or more memory cells of the NAND dies, where an amount of data stored to a given memory cell may be based on the configuration of memory cell used. For example, a memory system may include single level cells (SLCs) that may store one bit of data, multi-level cells (MLCs) that may store two bits of data, triple-level cells (TLCs) that may store three bits of data, or quad-level cells (QLCs) that may store four bits of data. As such, incorporating QLCs in memory systems may increase the storage capability of a NAND memory device (e.g., the amount of information that may be stored in a finite quantity of memory cells may increase). In some cases, however, QLCs of a memory system may be associated with longer access operations and higher bit error rates as compared to other types of cells (e.g., SLCs, MLCs, or TLCs). In some examples, a memory system that uses TLCs may increase data reliability compared to QLCs, but may experience a reduction in the data capacity. As such, it may be advantageous for a user to configure a quantity of QLCs of the memory system based on reliability, timing, and storage parameters defined by the user.

As described herein, the memory system may first write data to a first set of memory cells (e.g., SLCs, MLCs, TLCs, or a combination thereof) and may later transfer a portion of the data to a second set of memory cells (e.g., QLCs). In some examples, the memory system may analyze the characteristics of the programmed data to determine whether the data is to be transferred from the first set of memory cells to the second set of memory cells. For instance, the memory system may analyze the temperature of the memory system when the data was initially written to the first set of memory cells. Additionally, or alternatively, the host system may indicate a type of the data (e.g., indicate the data as system oriented or non-system oriented). Additionally, or alternatively, the memory system may identify a read occurrence associated with the data. Additionally, or alternatively, the host system may configure a target storage capacity threshold for the memory system. The techniques described for an adaptive QLC storage configuration may allow the memory system to benefit from both the storage reliability provided by some types of memory cells (e.g., SLCs, MLCs, and TLCs) and the storage capacity provided by other types of memory cells (e.g., QLC).

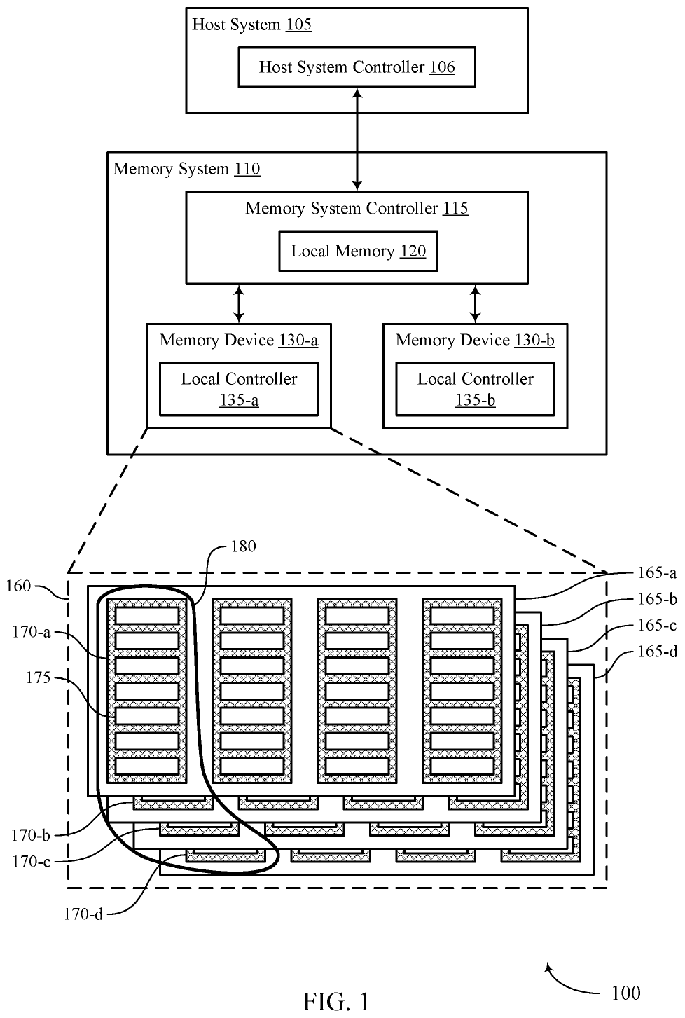

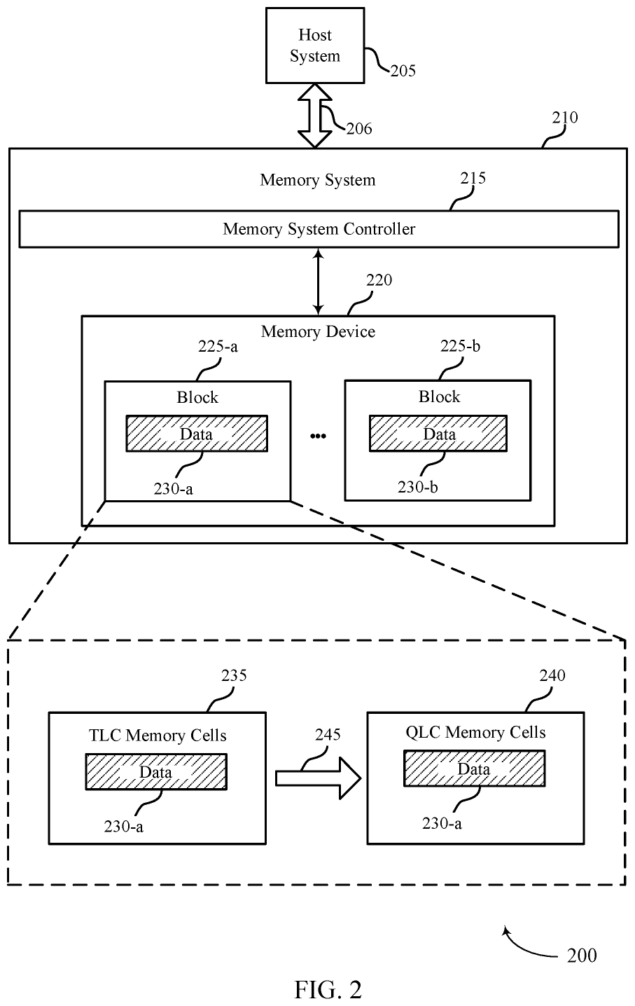

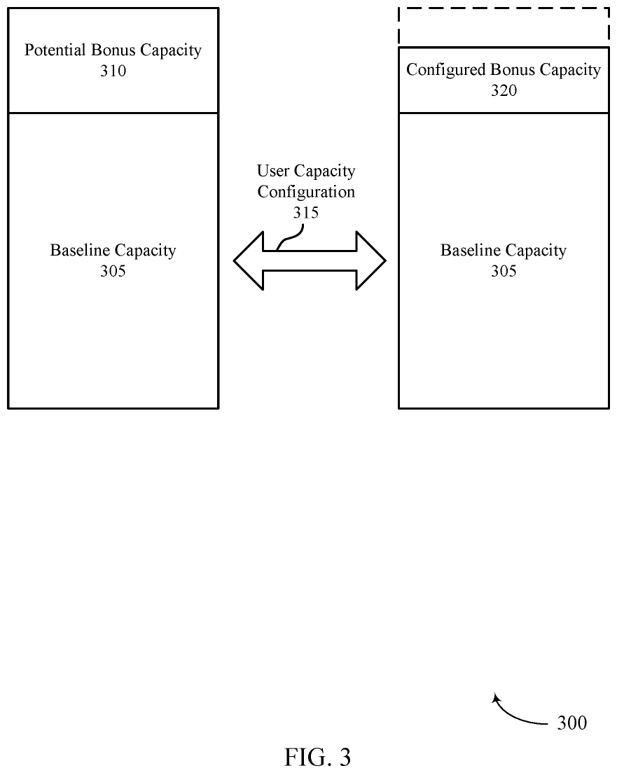

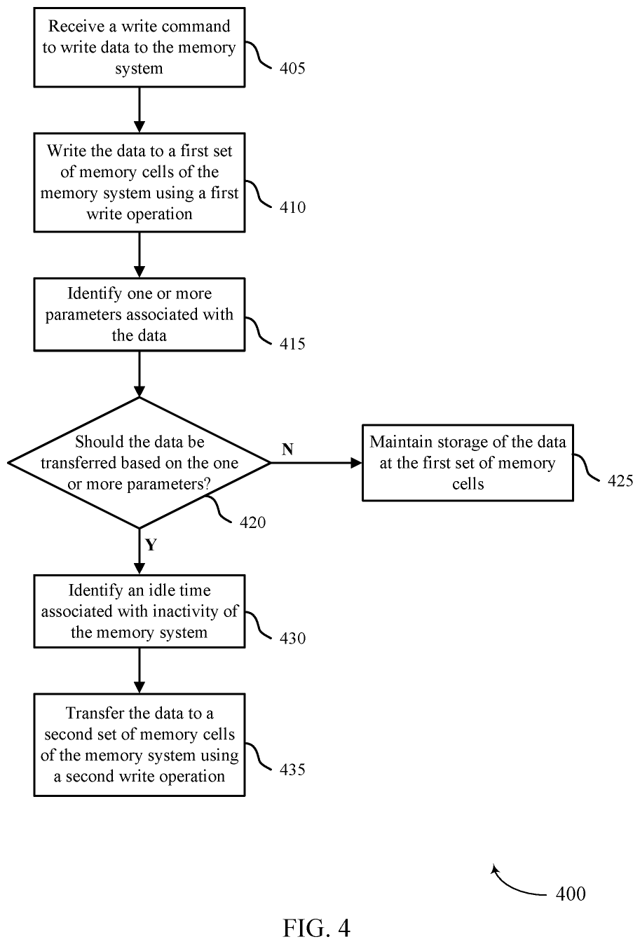

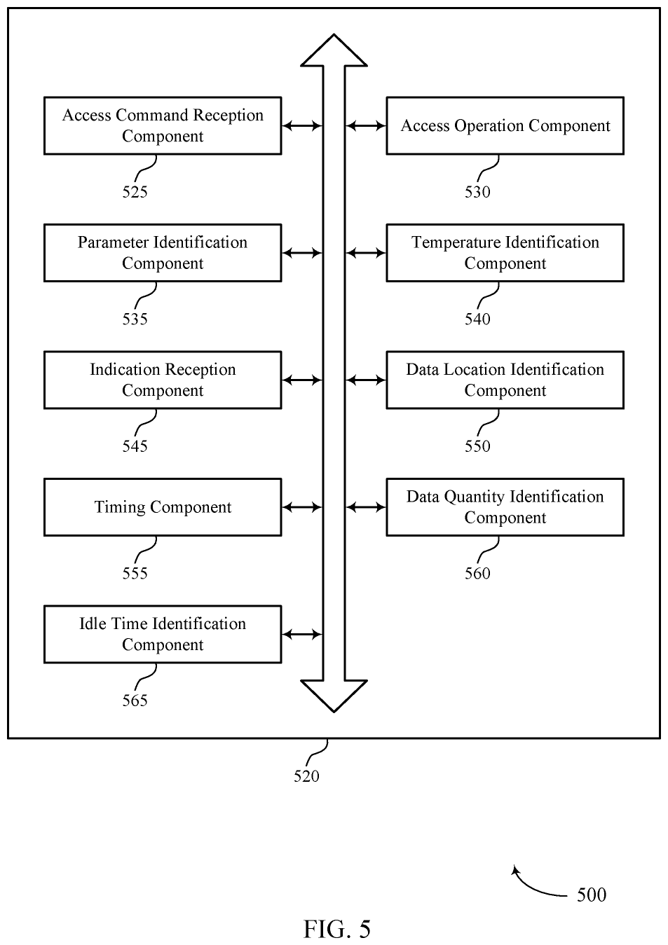

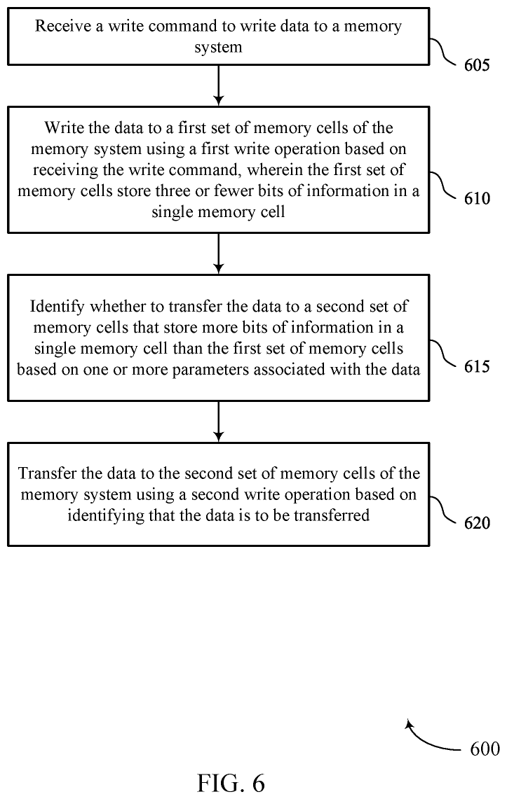

Features of the disclosure are initially described in the context of systems with reference to FIGS. 1 and 2. Features of the disclosure are described in the context of a storage capacity diagram and a process flow with reference to FIGS. 3 and 4. These and other features of the disclosure are further illustrated by and described in the context of an apparatus diagram and flowchart that relate to variable density storage device with reference to FIGS. 5 and 6.

FIG. 1 illustrates an example of a system 100 that supports variable density storage device in accordance with examples as disclosed herein. The system 100 includes a host system 105 coupled with a memory system 110.

A memory system 110 may be or include any device or collection of devices, where the device or collection of devices includes at least one memory array. For example, a memory system 110 may be or include a Universal Flash Storage (UFS) device, an embedded Multi-Media Controller (eMMC) device, a flash device, a universal serial bus (USB) flash device, a secure digital (SD) card, a solid-state drive (SSD), a hard disk drive (HDD), a dual in-line memory module (DIMM), a small outline DIMM (SO-DIMM), or a non-volatile DIMM (NVDIMM), among other possibilities.

The system 100 may be included in a computing device such as a desktop computer, a laptop computer, a network server, a mobile device, a vehicle (e.g., airplane, drone, train, automobile, or other conveyance), an Internet of Things (IoT) enabled device, an embedded computer (e.g., one included in a vehicle, industrial equipment, or a networked commercial device), or any other computing device that includes memory and a processing device.

The system 100 may include a host system 105, which may be coupled with the memory system 110. In some examples, this coupling may include an interface with a host system controller 106, which may be an example of a controller or control component configured to cause the host system 105 to perform various operations in accordance with examples as described herein. The host system 105 may include one or more devices and, in some cases, may include a processor chipset and a software stack executed by the processor chipset. For example, the host system 105 may include an application configured for communicating with the memory system 110 or a device therein. The processor chipset may include one or more cores, one or more caches (e.g., memory local to or included in the host system 105), a memory controller (e.g., NVDIMM controller), and a storage protocol controller (e.g., peripheral component interconnect express (PCIe) controller, serial advanced technology attachment (SATA) controller). The host system 105 may use the memory system 110, for example, to write data to the memory system 110 and read data from the memory system 110. Although one memory system 110 is shown in FIG. 1, the host system 105 may be coupled with any quantity of memory systems 110.

The host system 105 may be coupled with the memory system 110 via at least one physical host interface. The host system 105 and the memory system 110 may, in some cases, be configured to communicate via a physical host interface using an associated protocol (e.g., to exchange or otherwise communicate control, address, data, and other signals between the memory system 110 and the host system 105). Examples of a physical host interface may include, but are not limited to, a SATA interface, a UFS interface, an eMMC interface, a PCIe interface, a USB interface, a Fiber Channel interface, a Small Computer System Interface (SCSI), a Serial Attached SCSI (SAS), a Double Data Rate (DDR) interface, a DIMM interface (e.g., DIMM socket interface that supports DDR), an Open NAND Flash Interface (ONFI), and a Low Power Double Data Rate (LPDDR) interface. In some examples, one or more such interfaces may be included in or otherwise supported between a host system controller 106 of the host system 105 and a memory system controller 115 of the memory system 110. In some examples, the host system 105 may be coupled with the memory system 110 (e.g., the host system controller 106 may be coupled with the memory system controller 115) via a respective physical host interface for each memory device 130 included in the memory system 110, or via a respective physical host interface for each type of memory device 130 included in the memory system 110.

The memory system 110 may include a memory system controller 115 and one or more memory devices 130. A memory device 130 may include one or more memory arrays of any type of memory cells (e.g., non-volatile memory cells, volatile memory cells, or any combination thereof). Although two memory devices 130-a and 130-b are shown in the example of FIG. 1, the memory system 110 may include any quantity of memory devices 130. Further, if the memory system 110 includes more than one memory device 130, different memory devices 130 within the memory system 110 may include the same or different types of memory cells.

The memory system controller 115 may be coupled with and communicate with the host system 105 (e.g., via the physical host interface) and may be an example of a controller or control component configured to cause the memory system 110 to perform various operations in accordance with examples as described herein. The memory system controller 115 may also be coupled with and communicate with memory devices 130 to perform operations such as reading data, writing data, erasing data, or refreshing data at a memory device 130—among other such operations—which may generically be referred to as access operations. In some cases, the memory system controller 115 may receive commands from the host system 105 and communicate with one or more memory devices 130 to execute such commands (e.g., at memory arrays within the one or more memory devices 130). For example, the memory system controller 115 may receive commands or operations from the host system 105 and may convert the commands or operations into instructions or appropriate commands to achieve the desired access of the memory devices 130. In some cases, the memory system controller 115 may exchange data with the host system 105 and with one or more memory devices 130 (e.g., in response to or otherwise in association with commands from the host system 105). For example, the memory system controller 115 may convert responses (e.g., data packets or other signals) associated with the memory devices 130 into corresponding signals for the host system 105.

The memory system controller 115 may be configured for other operations associated with the memory devices 130. For example, the memory system controller 115 may execute or manage operations such as wear-leveling operations, garbage collection operations, error control operations such as error-detecting operations or error-correcting operations, encryption operations, caching operations, media management operations, background refresh, health monitoring, and address translations between logical addresses (e.g., logical block addresses (LBAs)) associated with commands from the host system 105 and physical addresses (e.g., physical block addresses) associated with memory cells within the memory devices 130.

The memory system controller 115 may include hardware such as one or more integrated circuits or discrete components, a buffer memory, or a combination thereof. The hardware may include circuitry with dedicated (e.g., hard-coded) logic to perform the operations ascribed herein to the memory system controller 115. The memory system controller 115 may be or include a microcontroller, special purpose logic circuitry (e.g., a field programmable gate array (FPGA), an application specific integrated circuit (ASIC), a digital signal processor (DSP)), or any other suitable processor or processing circuitry.

The memory system controller 115 may also include a local memory 120. In some cases, the local memory 120 may include read-only memory (ROM) or other memory that may store operating code (e.g., executable instructions) executable by the memory system controller 115 to perform functions ascribed herein to the memory system controller 115. In some cases, the local memory 120 may additionally, or alternatively, include static random access memory (SRAM) or other memory that may be used by the memory system controller 115 for internal storage or calculations, for example, related to the functions ascribed herein to the memory system controller 115.

A memory device 130 may include one or more arrays of non-volatile memory cells. For example, a memory device 130 may include NAND (e.g., NAND flash) memory, ROM, phase change memory (PCM), self-selecting memory, other chalcogenide-based memories, ferroelectric random access memory (RAM) (FeRAM), magneto RAM (MRAM), NOR (e.g., NOR flash) memory, Spin Transfer Torque (STT)-MRAM, conductive bridging RAM (CBRAM), resistive random access memory (RRAM), oxide based RRAM (OxRAM), electrically erasable programmable ROM (EEPROM), or any combination thereof.

Additionally, or alternatively, a memory device 130 may include one or more arrays of volatile memory cells. For example, a memory device 130 may include RAM memory cells, such as dynamic RAM (DRAM) memory cells and synchronous DRAM (SDRAM) memory cells.

In some examples, a memory device 130 may include (e.g., on a same die or within a same package) a local controller 135, which may execute operations on one or more memory cells of the respective memory device 130. A local controller 135 may operate in conjunction with a memory system controller 115 or may perform one or more functions ascribed herein to the memory system controller 115. For example, as illustrated in FIG. 1, a memory device 130-a may include a local controller 135-a and a memory device 130-b may include a local controller 135-b.

In some cases, a memory device 130 may be or include a NAND device (e.g., NAND flash device). A memory device 130 may be or include a die 160 (e.g., a memory die). For example, in some cases, a memory device 130 may be a package that includes one or more dies 160. A die 160 may, in some examples, be a piece of electronics-grade semiconductor cut from a wafer (e.g., a silicon die cut from a silicon wafer). Each die 160 may include one or more planes 165, and each plane 165 may include a respective set of blocks 170, where each block 170 may include a respective set of pages 175, and each page 175 may include a set of memory cells.

In some cases, a NAND memory device 130 may include memory cells configured to each store one bit of information, which may be referred to as SLCs. Additionally, or alternatively, a NAND memory device 130 may include memory cells configured to each store multiple bits of information, which may be referred to as MLCs if configured to each store two bits of information, as TLCs if configured to each store three bits of information, as QLCs if configured to each store four bits of information, or more generically as multiple-level memory cells. Multiple-level memory cells may provide greater density of storage relative to SLC memory cells but may, in some cases, involve narrower read or write margins or greater complexities for supporting circuitry.

In some cases, planes 165 may refer to groups of blocks 170, and in some cases, concurrent operations may be performed on different planes 165. For example, concurrent operations may be performed on memory cells within different blocks 170 so long as the different blocks 170 are in different planes 165. In some cases, an individual block 170 may be referred to as a physical block, and a virtual block 180 may refer to a group of blocks 170 within which concurrent operations may occur. For example, concurrent operations may be performed on blocks 170-a, 170-b, 170-c, and 170-d that are within planes 165-a, 165-b, 165-c, and 165-d, respectively, and blocks 170-a, 170-b, 170-c, and 170-d may be collectively referred to as a virtual block 180. In some cases, a virtual block may include blocks 170 from different memory devices 130 (e.g., including blocks in one or more planes of memory device 130-a and memory device 130-b). In some cases, the blocks 170 within a virtual block may have the same block address within their respective planes 165 (e.g., block 170-a may be “block 0” of plane 165-a, block 170-b may be “block 0” of plane 165-b, and so on). In some cases, performing concurrent operations in different planes 165 may be subject to one or more restrictions, such as concurrent operations being performed on memory cells within different pages 175 that have the same page address within their respective planes 165 (e.g., related to command decoding, page address decoding circuitry, or other circuitry being shared across planes 165).

In some cases, a block 170 may include memory cells organized into rows (pages 175) and columns (e.g., strings, not shown). For example, memory cells in a same page 175 may share (e.g., be coupled with) a common word line, and memory cells in a same string may share (e.g., be coupled with) a common digit line (which may alternatively be referred to as a bit line).

For some NAND architectures, memory cells may be read and programmed (e.g., written) at a first level of granularity (e.g., at the page level of granularity) but may be erased at a second level of granularity (e.g., at the block level of granularity). That is, a page 175 may be the smallest unit of memory (e.g., set of memory cells) that may be independently programmed or read (e.g., programed or read concurrently as part of a single program or read operation), and a block 170 may be the smallest unit of memory (e.g., set of memory cells) that may be independently erased (e.g., erased concurrently as part of a single erase operation). Further, in some cases, NAND memory cells may be erased before they can be re-written with new data. Thus, for example, a used page 175 may, in some cases, not be updated until the entire block 170 that includes the page 175 has been erased.

In some cases, to update some data within a block 170 while retaining other data within the block 170, the memory device 130 may copy the data to be retained to a new block 170 and write the updated data to one or more remaining pages of the new block 170. The memory device 130 (e.g., the local controller 135) or the memory system controller 115 may mark or otherwise designate the data that remains in the old block 170 as invalid or obsolete and may update a logical-to-physical (L2P) mapping table to associate the logical address (e.g., LBA) for the data with the new, valid block 170 rather than the old, invalid block 170. In some cases, such copying and remapping may be performed instead of erasing and rewriting the entire old block 170 due to latency or wearout considerations, for example. In some cases, one or more copies of an L2P mapping table may be stored within the memory cells of the memory device 130 (e.g., within one or more blocks 170 or planes 165) for use (e.g., reference and updating) by the local controller 135 or memory system controller 115.

In some cases, a memory system 110 may utilize a memory system controller 115 to provide a managed memory system that may include, for example, one or more memory arrays and related circuitry combined with a local (e.g., on-die or in-package) controller (e.g., local controller 135). An example of a managed memory system is a mNAND system.

The system 100 may include any quantity of non-transitory computer readable media that support variable density storage device. For example, the host system 105 (e.g., a host system controller 106), the memory system 110 (e.g., a memory system controller 115), or a memory device 130 (e.g., a local controller 135) may include or otherwise may access one or more non-transitory computer readable media storing instructions (e.g., firmware, logic, code) for performing the functions ascribed herein to the host system 105, the memory system 110, or a memory device 130. For example, such instructions, if executed by the host system 105 (e.g., by a host system controller 106), by the memory system 110 (e.g., by a memory system controller 115), or by a memory device 130 (e.g., by a local controller 135), may cause the host system 105, the memory system 110, or the memory device 130 to perform associated functions as described herein.

In some examples, the memory system 110 may write data to a first set of memory cells (e.g., SLCs, MLCs, TLCs, or a combination thereof) and may later transfer a portion of the data to a second set of memory cells (e.g., QLCs). In some examples, the memory system 110 may analyze the characteristics of the programmed data to determine whether the data is to be transferred from the first set of memory cells to the second set of memory cells. For instance, the memory system 110 may analyze the temperature of the memory system 110 when the data was initially written to the first set of memory cells. Additionally, or alternatively, the host system 105 may indicate a type of the data (e.g., indicate the data as system oriented or non-system oriented). Additionally, or alternatively, the memory system 110 may identify a read occurrence associated with the data. Additionally, or alternatively, the host system 105 may configure a target storage capacity threshold for the memory system 110. The techniques described for an adaptive QLC storage configuration may allow the memory system 110 to benefit from both the storage reliability provided by lower level cells (e.g., SLCs, MLCs, and TLCs) and the storage capacity provided by QLCs.

FIG. 2 illustrates an example of a system 200 that supports variable density storage device in accordance with examples as disclosed herein. The system 200 may include a host system 205 and a memory system 210. In some cases, the host system 205 and the memory system 210 may represent a host system 205 105 as described with reference to FIG. 1. In some examples, the host system 205 may be coupled with the memory system 210 via an interface 206. The memory system 210 may be configured to store data 230 to a first set of memory cells and transfer a portion of the data 230 to a second set of memory cells based on identifying one or more parameters associated with the data 230, which may improve the overall reliability and storage capacity of the memory system 210.

The memory system 210 may include a memory device 220 that includes one or more blocks 225 of non-volatile memory cells. For example, the memory device 220 may include at least a block 225-a a block 225-b, and any quantity of intervening blocks 225 in between. In some cases, the blocks 225 may be examples of blocks 170, as described with reference to FIG. 1.

In some cases, the memory system controller 215 may be coupled with the memory device 220. Accordingly, the memory system controller 215 may perform access operations on the blocks 225 of the memory device 220. In some examples, the memory system 210 performing one or access operations may be based on receiving one or more access commands from the host system 205. For example, the memory system controller 215 may receive a first write command to write the data 230-a to the memory system 210. As such, the memory system controller 215 may write the data 230-a to memory cells of the block 225-a.

In some instances, the blocks 225 may represent physical blocks of memory cells. For example, the memory cells of block 225-a may include memory cells storing one bit of data 230 (e.g., one or more SLCs), two bits of data 230 (e.g., one or more MLCs), three bits of data 230 (e.g., one or more TLCs), or four bits of data 230 (e.g., one or more QLCs). Additionally, the memory cells of block 225-b may include the same or similar memory cells (e.g., memory cells storing one or more bits of data 230). Each of the blocks 225 may store respective data 230. For example, the block 225-a may store data 230-a and block 225-b may store data 230-b.

Based on the density of information stored in each cell, QLCs may be able to store a greater amount of data 230 relative to lower-level cells (e.g., SLCs, MLCs, and TLCs). As such, memory systems 210 that store data to QLCs may increase the capacity of the memory devices 220 using the same quantity of memory cells as using lower-level cells. Additionally, or alternatively, QLCs may lower a cost per unit capacity of the memory system 210 by increasing the storage capacity within the same physical footprint of the memory devices 220. In some cases, however, QLCs may have an associated lower cell endurance compared to the lower level cells. For example, a QLC may hold 16 charge states which may correspond to 16 respective thresholds voltages that map to four bits per cell (e.g., 0000, 0001, 0010, . . . , 1111), while a TLC may hold 8 charge states which may correspond to 8 respective threshold voltages that map to three bits per cell (e.g., 000, 001, 010, . . . , 111). As such, a QLC may hold twice the quantity of charge states within a same voltage range as a TLC, which may increase an exposure to noise and a quantity of errors in the data 230 (e.g., bit flip occasions). Additionally, or alternatively, the increase in charge states may increase a duration of time associated with performing an access operation on a QLC.

In some examples, the memory system 210 may use lower level cells to increase the durability and reliability of the set of memory cells. For example, TLCs relative to QLCs may perform more writes per cell during the life-time of the memory system 210. Additionally, or alternatively, TLCs may have a decrease duration of time associated with performing access operations relative to QLCs. Based on TLCs holding 8 charge states, memory systems 210 that use TLCs may decrease the error occurrence of the data 230. However, lower level cells may be associated with a lower data density relative to QLCs, and as such may store less data 230 in a same physical footprint of the memory device 220.

As such, the memory system 210 may benefit from both the data reliability of lower level cells and the increased data capacity of QLCs by operating in accordance with the techniques described herein. In some examples, the memory system 210 may determine to selectively move one or more portions of data 230 from lower level cells to QLCs in accordance with one or more parameters associated with the data 230.

For instance, the memory system controller 215 may first receive a write command to write data 230 to the memory system 210. For example, with reference to FIG. 2, the memory system controller 215 may write, using a first write operation, the data 230-a and the data 230-b in response to receiving the write command. In some cases, the data 230-a and 230-b may first be stored to lower level memory cells (e.g., SLCs, MLCs, or TLCs). As illustrated in FIG. 2, the data 230-a may be stored to TLC memory cells 235. While FIG. 2 illustrates data 230 as initially being stored to TLC memory cells 235, it is understood that data 230 may be initially stored to one or more types of lower level cells (e.g., SLCs, MLCs, and TLCs).

After storing the data 230 to the first set of memory cells (e.g., TLC memory cells 235), the memory system controller 215 may identify whether to transfer the data 230 to a second set of memory cells that may store more bits of information in a single memory cells than the first set of memory cells (e.g., QLC memory cells 240). For example, as illustrated in FIG. 2, the memory system controller 215 may identify to transfer the data 230-a, via a transfer operation 245, from TLC memory cells 235 to the QLC memory cells 240. In some examples, the transfer operation 245 may be a second write operation in which the memory system controller reads the data 230-a from the TLC memory cells 235 and writes the data 230-a to the QLC memory cells 240.

In some examples, the memory system controller 215 may perform the transfer operation 245 in response to a temperature of the data 230-a during the initial write operation. For example, the memory system controller 215 may write a temperature of a given block 225 during the initial write operation of the respective data 230. If the temperature recorded for the given block 225 satisfies one or more temperature parameters (or is outside a nominal temperature range), the memory system controller 215 may transfer perform the transfer operation 245. For example, a temperature that is higher than an operational range of the memory system during the initial write may result in an increase in data errors for the given block 225. As such, if the temperature of the block 225 is above a first threshold while writing the data 230-a, the memory system controller 215 may refrain from transferring the data 230-a to the QLC memory cells. In another example, a temperature that is lower than an operational range of the memory system during the initial write may result in an increase in data errors for the given block 225. As such, if the temperature of the block 225 is below a second threshold while writing the data 230-a, the memory system controller 215 may refrain from transferring the data 230-a to the QLC memory cells. Additionally, or alternatively, if the temperature of the block 225-a is within the operation range of temperatures (e.g., below the first threshold or above the second threshold), the memory system controller 215 may perform the transfer operation 245 on the data 230-a. In some examples, the temperature threshold may be indicated and configured by the host system 205 controller. Accordingly, a user may configure the temperature threshold. Additionally, or alternatively, the temperature threshold may be configured at the memory system 210 during manufacturing.

Additionally, or alternatively, the memory system controller 215 may perform the transfer operation 245 in accordance with a type of data written to a block 225. In some examples, a portion of data 230 may be defined as system oriented (e.g., data used in initial start-up of the memory system 210, data used for vehicle operations or safety, data downloaded during manufacturing of the memory system 210, etc.). In some examples, a portion of data 230 may be defined as non-system oriented (e.g., data that may be redownloaded post manufacturing if corrupted or data not used in the start-up or system operations of the memory system 210). As such, the memory system controller 215 may transfer non-system oriented data to QLC memory cells 240. For example, the memory system controller 215 may receive a flag indicating that the data 230 is non-system oriented data and perform the transfer operation 245 for data 230-a in response to receiving the flag. In some cases, the principles related to system-oriented data may be applied to any data that is marked as critical. If data has a higher reliability requirement or a higher error bit rate requirement than other data, the memory system may refrain from transferring the data to higher level cells (e.g., QLC).

In some examples, the memory system controller 215 may determine the type of data associated with the data 230-a in accordance with the region of the memory device 220 the data 230-a is written to. For example, the memory system 210 may identify that the block 225-a is associated with a first region of the memory device 220, where the first region of the memory device 220 stores non-system oriented data (or non-critical data). As such, the memory system 210 may perform the transfer operation 245 on the data 230-a in response to identifying that the data 230-a is stored at block 225-a which is associated with the first region of the memory device 220. In some examples, a region of the memory device may be a physical location of the memory device or a logical mapping to a set of blocks 225, memory cells, or a combination thereof.

Additionally, or alternatively, the memory system controller 215 may perform the transfer operation 245 in accordance with the read occurrence associated with the data 230-a. For example, the memory system controller 215 may receive from the host system 205, an indication of a duration of time associated with performing a start-up procedure. As such, if the memory system controller 215 identifies that the data 230-a is accessed during the duration of time indicated, then the memory system controller 215 may identify that the data 230-a is system oriented data and refrain from performing the transfer operation 245. If the memory system controller 215 identifies that the data 230-a is accessed after the duration of time indicated, then the memory system controller 215 may identify that the data 230-a is non-system oriented data and perform the transfer operation 245. In some examples, the ‘hotness’ of the data (e.g., how frequently the data is accessed) may be identified by the memory system as part of determining whether to transfer the data to higher level cells (e.g., QLC).

In some examples, a region of the memory device 220 may store data 230 that is associated with performing the start-up procedure. For example, block 225-b may be associated with a first region of the memory device 220 used in performing the start-up procedure and block 225-a may be associated with a second region of the memory device 220 that is different from the first portion (e.g., not used to perform the start-up procedure). As such, the memory system controller 215 may perform the transfer operation 245 on data 230-a in response to identifying that the block 225-a is associated with the second region of the memory device 220.

Additionally, or alternatively, the memory system controller 215 may perform the transfer operation 245 in accordance with a storage capacity configuration of the memory system 210. For example, the memory system controller 215 may receive from the host system 205, an indication of a data storage configuration that indicates a data quantity threshold for storing data 230 to lower level memory cells. For instance, the data quantity threshold may configure a lower bound on the quantity of data 230 at the memory system 210 that may first be stored to lower level cells before transferring data 230 to QLC memory cells 240. As such, if the memory system controller 215 identifies that the quantity of data 230 stored at the memory system 210 is above the configured threshold, the memory system controller 215 may perform the transfer operation 245 for data 230-a. The storage capacity configuration may allow a user of the memory system 210 to dynamically adjust the quantity of data 230 stored to lower-level cells which may dynamically change the amount of data 230 that may be stored to QLC memory cells 240 (e.g., a bonus data 230 storage capacity).

By selectively transferring portions of data 230 to QLCs, the memory system 210 may benefit from both the efficiency and data reliability associated with lower level cells and the additional storage capacity associated with QLCs. Additionally, or alternatively, the one or more indications of thresholds configured by host system 205 may allow for the user to dynamically adjust the storage capabilities of the memory system 210. The adaptive storage capabilities may allow the user to configure the memory system 210 based on the type of data 230 stored. For example, if the memory system 210 is associated with an emphasis on data reliability, the host system 205 may indicate to increase the data quantity threshold for storing data 230 to lower level memory cells. If the memory system 210 is associated with an emphasis on data reliability the host system 205 may indicate to decrease the data quantity threshold, allowing for more data 230 to be stored at QLCs.

FIG. 3 illustrates an example of a storage capacity diagram 300 that supports variable density storage device in accordance with examples as disclosed herein. The storage capacity diagram 300 may incorporate aspects of systems 100 and 200. For example, a baseline capacity 305 for data storage may be with reference to a baseline data storage of a memory system 110 or a memory system 210 as respectively described with reference FIGS. 1 and 2.

According to the techniques described herein, a memory system may have a configurable data storage capacity based one or more configurations indicated by a user (e.g., via a host system). For example, the memory system may be configured such that each memory cell of the memory system may be a TLC. In such examples, the memory system would have configured data storage capacity equal to the baseline capacity 305.

Additionally, or alternatively, the memory system may be configured such that a first portion of memory cells of the memory system are TLCs, and a second portion of memory cells are QLCs. By increasing the quantity of memory cells that are QLCs, the memory system may increase the storage capacity of the memory system. As illustrated in FIG. 3, a potential bonus capacity 310 may depict the amount of additional storage capacity at the memory system if the total possible quantity of QLCs are configured for storage at the memory system. As such, the memory system may have a total potential storage capacity equal to the sum of the baseline capacity 305 and the potential bonus capacity 310. In some cases, the memory cells of the memory system may be examples of on-the-fly (OTF) memory cells, where a memory cell may be of a first cell type (e.g., SLC, MLC, TLC, or QLC) and may be reconfigured to a second cell type during a reconfiguration operation. For example, a TLC from the first portion of memory cells may be reconfigured as a QLC from the second portion of memory cells. Additionally, or alternatively, the quantity of SLCs, MLCs, TLCs, and QLCs may be configured and fixed during manufacturing.

During an initialization of the memory system, one or more instances of a user capacity configuration 315 may set a configured bonus capacity 320. As such, the configured bonus capacity 320 may be less than or equal to the potential bonus capacity 310. In some examples, a user or vendor of the memory system may configure one or more QLC transferring parameters (e.g., the one or more parameters described with reference to FIG. 2), which may impact the size of the configured bonus capacity 320. For example, a user may transmit, via a host system coupled with the memory system, a flag indicating whether a portion of data may be transferred to QLC, where transferring the portion of data to QLC may increase the configured bonus capacity 320.

In some examples, the user may determine that a primary characteristic of the memory system is to have a larger configured storage capacity. For instance, the data stored to the memory system may be associated with a relatively large portion of non-system oriented data. As such, the user may determine to increase the number of configured QLC cells in the memory system to increase the configured bonus capacity 310. For example, the user may indicate via the host system, to decrease a quantity data threshold for storing data to lower level memory cells (e.g., SLCs, MLCs, TLCs). Based on decreasing the quantity data threshold, a larger portion of the data of the memory system may be stored to QLC memory cells, increasing the configured bonus capacity 320, which may increase the total storage capacity of the memory system. Additionally, or alternatively, the user may increase the frequency of flags indicating to store data to QLCs, increasing the configured bonus capacity 320, which may increase the total storage capacity of the memory system.

In some examples, the user may determine that a primary characteristic of the memory system is data reliability. For instance, the data stored to the memory system may be associated with a relatively large portion of system oriented data. As such, the user may determine to decrease the number of configured QLC cells in the memory system to increase the portion of data stored to lower level cells, which may be associated with greater data reliability. For example, the user may indicate via the host system, to increase a quantity data threshold for storing data to lower level memory cells (e.g., SLCs, MLCs, TLCs). Based on increasing the quantity data threshold, a larger portion of the data of the memory system may be stored to the lower level memory cells, decreasing the configured bonus capacity 320, which may increase the data reliability of the memory system. Additionally, or alternatively, the user may increase the frequency of flags indicating to store data to lower level cells, which may increase the data reliability of the memory system.

FIG. 4 illustrates an example of a process flow 400 that supports variable density storage device in accordance with examples as disclosed herein. In some examples, process flow 400 may be implemented by one or more aspects of systems 100 and 200. For instance, process flow 400 may be implemented by a memory system 110 as described with reference to FIG. 1 or a memory system 210 as described with reference to FIG. 2. In some examples, process flow 400 may correspond to one or more writing operations that may transfer portions of data from a first type of memory cells to a second type of memory cells based on one or more parameters associated with the portions of data. Aspects of the process flow 400 may be implemented by a controller, among other components. Additionally, or alternatively, aspects of the process flow 400 may be implemented as instructions stored in memory (e.g., firmware stored in a memory coupled with a controller). For example, the instructions, in response to being executed by a controller (e.g., the memory system controller 115), may cause the controller to perform the operations of the process flow 400.

At 405, the memory system controller may receive a write command to write data to the memory system.

At 410, the memory system controller may write the data to a first set of memory cells of the memory system using a first write operation based on receiving the write command. In some examples, the first set of memory cells may store three or fewer bits of information in a single memory cell. For example, the first set of memory cells may be SLCs, MLCs, TLCs, or a combination thereof.

At 415, the memory system controller may identify one or more parameters associated with the data, and at 420 identify whether to transfer the data to a second set of memory cells based on one or more parameters associated with the data. In some examples, the second set of memory cells may store more bits of information in a single memory cell than the first set of memory cells. For example, the second set of memory cells may be examples of QLCs.

If at 420, the one or more parameters indicate that the data may not be transferred, then at 425, the memory system controller may maintain storage of the data at the first set of memory cells.

If at 420, the one or more parameters indicate that the data may be transferred, then at 430, the memory system controller may identify an idle time associated with inactivity of the memory system. At 435, the memory system controller may transfer the data to the second set of memory cells of the memory system using a second write operation based on identifying both that the data is to be transferred and identifying the idle time of the memory system.

In some examples, the one or more parameters associated with the data may include a temperature of the data during the first write operation. In such examples, transferring the data to the second set of memory cells of the memory system may be based on the temperature of the data satisfying a temperature threshold. For example, if the temperature is above a configured temperature threshold, then at 435, the memory system may determine to transfer the data to the second set of memory cells. In some examples, the host system may indicate the configured temperature threshold to the memory system controller. In some examples, the temperature threshold may be configured at the memory system controller during manufacturing.

Additionally, or alternatively, the one or more parameters may be associated with a flag indicating that the data is of a first type (e.g., non-system oriented data as described with reference to FIG. 2) or a second type (e.g., system oriented data as described with reference to FIG. 2). If the flag indicates that the data is of the first type, then at 435, the memory system may transfer data to the second set of memory cells. If the flag indicates that the data is of the second time, then at 425, the memory system may maintain storage of the data at the first set of memory cells.

Additionally, or alternatively, the one or more parameters may be associated with the memory system identifying that the data is associated with a first region of the memory system. In some examples, the first region of the memory system may store data of the first type. As such at 435, the memory system controller may transfer the data to the second set of memory cells of the memory system based on writing the data to the first region associated with the first type of data.

Additionally, or alternatively, the one or more parameters may be associated with an indication of a duration of time for a start-up procedure of the memory system. If the memory system controller identifies during the start-up procedure, that the data is accessed after the duration of time indicated, then at 435, the memory system controller may transfer the data to the second set of memory cells. If the memory system controller identifies during the start-up procedure, that the data is accessed during the duration of time indicated, then at 325, the memory system controller may maintain storage of the data at the first set of memory cells. In some examples, the memory system controller may receive from the host system, the indication of duration of time associated with performing the start-up procedure.

Additionally, or alternatively, the one or more parameters may be based on the memory system identifying whether the data is stored at a portion of the memory system associated with performing the start-up procedure. For example, if the memory system controller identifies that the data is stored at a first region associated with performing the start-up procedure, then at 425, the memory system controller may maintain storage of the data at the first set of memory cells. If the memory system controller identifies that the data is stored at a second region of the memory system different than the first region, then at 435, the memory system may transfer the data to the second set of memory cells.

Additionally, or alternatively, the one or more parameters may be associated with a data storage configuration of the memory system. For example, the memory system may receive from the host system, an indication of the data storage configuration that indicates a data quantity threshold for storing the second type of data (e.g., system oriented data). If the memory system controller identifies that a quantity of data stored at the memory system satisfies the data quantity threshold (e.g., is above the threshold), then at 435, the memory system controller may transfer the data to the second set of memory cells. If the memory system controller identifies that a quantity of data stored at the memory system does not satisfy the data quantity threshold (e.g., is below the threshold), then at 425, the memory system controller may maintain the data at the first set of memory cells. In some examples, the host system may transmit one or more indications of the data storage configuration which may dynamically update the data quantity threshold.

FIG. 5 shows a block diagram 500 of a memory system 520 that supports variable density storage device in accordance with examples as disclosed herein. The memory system 520 may be an example of aspects of a memory system as described with reference to FIGS. 1 through 4. The memory system 520, or various components thereof, may be an example of means for performing various aspects of variable density storage device as described herein. For example, the memory system 520 may include an access command reception component 525, an access operation component 530, a parameter identification component 535, a temperature identification component 540, an indication reception component 545, a data location identification component 550, a timing component 555, a data quantity identification component 560, an idle time identification component 565, or any combination thereof. Each of these components may communicate, directly or indirectly, with one another (e.g., via one or more buses).

The access command reception component 525 may be configured as or otherwise support a means for receiving a write command to write data to a memory system. The access operation component 530 may be configured as or otherwise support a means for writing the data to a first set of memory cells of the memory system using a first write operation based at least in part on receiving the write command, where the first set of memory cells store three or fewer bits of information in a single memory cell. The parameter identification component 535 may be configured as or otherwise support a means for identifying whether to transfer the data to a second set of memory cells that store more bits of information in a single memory cell than the first set of memory cells based at least in part on one or more parameters associated with the data. In some examples, the access operation component 530 may be configured as or otherwise support a means for transferring the data to the second set of memory cells of the memory system using a second write operation based at least in part on identifying that the data is to be transferred.

In some examples, the temperature identification component 540 may be configured as or otherwise support a means for writing, while writing the data to the first set of memory cells, a temperature of the data during the first write operation, the one or more parameters associated with the data includes the temperature, where transferring the data to the second set of memory cells of the memory system is based at least in part on the temperature of the data satisfying a temperature threshold.

In some examples, the indication reception component 545 may be configured as or otherwise support a means for receiving, as part of the write command, a flag indicating that the data is a first type, the one or more parameters associated with the data including the flag, where transferring the data to the second set of memory cells of the memory system is based at least in part on receiving the flag indicating that the data is the first type.

In some examples, the data location identification component 550 may be configured as or otherwise support a means for identifying that the data is associated with a first region of the memory system, where the first region of the memory system stores a first type of data and the one or more parameters associated with the data includes an indication of the first region, where transferring the data to the second set of memory cells of the memory system is based at least in part on writing the data to the first region associated with the first type of data.

In some examples, the indication reception component 545 may be configured as or otherwise support a means for receiving an indication of a duration of time associated with performing a start-up procedure, the one or more parameters associated with the data including the indication of the duration. In some examples, the timing component 555 may be configured as or otherwise support a means for identifying, during the start-up procedure, that the data is accessed after the duration of time indicated, where transferring the data to the second set of memory cells of the memory system is based at least in part on identifying that the data is accessed after the duration of time indicated.

In some examples, the data location identification component 550 may be configured as or otherwise support a means for identifying that the data is stored to a first region of the memory system that is different than a second region associated with performing a start-up procedure, where, transferring the data to the second set of memory cells of the memory system is based at least in part on identifying that the data is stored to the first region.

In some examples, the indication reception component 545 may be configured as or otherwise support a means for receiving an indication of a data storage configuration of the memory system, where the data storage configuration indicates a data quantity threshold for storing a second type of data to the memory system, the one or more parameters associated with the data including the data storage configuration. In some examples, the data quantity identification component 560 may be configured as or otherwise support a means for identifying that a quantity of data stored to the memory system is of the second type and that the quantity of data stored satisfies the data quantity threshold, where transferring the data to the second set of memory cells of the memory system is based at least in part on identifying that the data quantity threshold is satisfied.

In some examples, the idle time identification component 565 may be configured as or otherwise support a means for identifying an idle time associated with inactivity of the memory system, where transferring the data to the second set of memory cells of the memory system is based at least in part on identifying the idle time.

In some examples, the first set of memory cells include TLCs, and the second set of memory cells include QLCs.

FIG. 6 shows a flowchart illustrating a method 600 that supports variable density storage device in accordance with examples as disclosed herein. The operations of method 600 may be implemented by a memory system or its components as described herein. For example, the operations of method 600 may be performed by a memory system as described with reference to FIGS. 1 through 5. In some examples, a memory system may execute a set of instructions to control the functional elements of the device to perform the described functions. Additionally, or alternatively, the memory system may perform aspects of the described functions using special-purpose hardware.

At 605, the method may include receiving a write command to write data to a memory system. The operations of 605 may be performed in accordance with examples as disclosed herein. In some examples, aspects of the operations of 605 may be performed by an access command reception component 525 as described with reference to FIG. 5.

At 610, the method may include writing the data to a first set of memory cells of the memory system using a first write operation based at least in part on receiving the write command, where the first set of memory cells store three or fewer bits of information in a single memory cell. The operations of 610 may be performed in accordance with examples as disclosed herein. In some examples, aspects of the operations of 610 may be performed by an access operation component 530 as described with reference to FIG. 5.

At 615, the method may include identifying whether to transfer the data to a second set of memory cells that store more bits of information in a single memory cell than the first set of memory cells based at least in part on one or more parameters associated with the data. The operations of 615 may be performed in accordance with examples as disclosed herein. In some examples, aspects of the operations of 615 may be performed by a parameter identification component 535 as described with reference to FIG. 5.

At 620, the method may include transferring the data to the second set of memory cells of the memory system using a second write operation based at least in part on identifying that the data is to be transferred. The operations of 620 may be performed in accordance with examples as disclosed herein. In some examples, aspects of the operations of 620 may be performed by an access operation component 530 as described with reference to FIG. 5.

In some examples, an apparatus as described herein may perform a method or methods, such as the method 600. The apparatus may include features, circuitry, logic, means, or instructions (e.g., a non-transitory computer-readable medium storing instructions executable by a processor), or any combination thereof for performing the following aspects of the present disclosure:

Aspect 1: A method, apparatus, or non-transitory computer-readable medium including operations, features, circuitry, logic, means, or instructions, or any combination thereof for receiving a write command to write data to a memory system; writing the data to a first set of memory cells of the memory system using a first write operation based at least in part on receiving the write command, where the first set of memory cells store three or fewer bits of information in a single memory cell; identifying whether to transfer the data to a second set of memory cells that store more bits of information in a single memory cell than the first set of memory cells based at least in part on one or more parameters associated with the data; and transferring the data to the second set of memory cells of the memory system using a second write operation based at least in part on identifying that the data is to be transferred.

Aspect 2: The method, apparatus, or non-transitory computer-readable medium of aspect 1, further including operations, features, circuitry, logic, means, or instructions, or any combination thereof for writing, while writing the data to the first set of memory cells, a temperature of the data during the first write operation, the one or more parameters associated with the data includes the temperature, where transferring the data to the second set of memory cells of the memory system is based at least in part on the temperature of the data satisfying a temperature threshold.

Aspect 3: The method, apparatus, or non-transitory computer-readable medium of any of aspects 1 through 2, further including operations, features, circuitry, logic, means, or instructions, or any combination thereof for receiving, as part of the write command, a flag indicating that the data is a first type, the one or more parameters associated with the data including the flag, where transferring the data to the second set of memory cells of the memory system is based at least in part on receiving the flag indicating that the data is the first type.

Aspect 4: The method, apparatus, or non-transitory computer-readable medium of any of aspects 1 through 3, further including operations, features, circuitry, logic, means, or instructions, or any combination thereof for identifying that the data is associated with a first region of the memory system, where the first region of the memory system stores a first type of data and the one or more parameters associated with the data includes an indication of the first region, where transferring the data to the second set of memory cells of the memory system is based at least in part on writing the data to the first region associated with the first type of data.

Aspect 5: The method, apparatus, or non-transitory computer-readable medium of any of aspects 1 through 4, further including operations, features, circuitry, logic, means, or instructions, or any combination thereof for receiving an indication of a duration of time associated with performing a start-up procedure, the one or more parameters associated with the data including the indication of the duration and identifying, during the start-up procedure, that the data is accessed after the duration of time indicated, where transferring the data to the second set of memory cells of the memory system is based at least in part on identifying that the data is accessed after the duration of time indicated.

Aspect 6: The method, apparatus, or non-transitory computer-readable medium of any of aspects 1 through 5, further including operations, features, circuitry, logic, means, or instructions, or any combination thereof for identifying that the data is stored to a first region of the memory system that is different than a second region associated with performing a start-up procedure, where, transferring the data to the second set of memory cells of the memory system is based at least in part on identifying that the data is stored to the first region.

Aspect 7: The method, apparatus, or non-transitory computer-readable medium of any of aspects 1 through 6, further including operations, features, circuitry, logic, means, or instructions, or any combination thereof for receiving an indication of a data storage configuration of the memory system, where the data storage configuration indicates a data quantity threshold for storing a second type of data to the memory system, the one or more parameters associated with the data including the data storage configuration and identifying that a quantity of data stored to the memory system is of the second type and that the quantity of data stored satisfies the data quantity threshold, where transferring the data to the second set of memory cells of the memory system is based at least in part on identifying that the data quantity threshold is satisfied.

Aspect 8: The method, apparatus, or non-transitory computer-readable medium of any of aspects 1 through 7, further including operations, features, circuitry, logic, means, or instructions, or any combination thereof for identifying an idle time associated with inactivity of the memory system, where transferring the data to the second set of memory cells of the memory system is based at least in part on identifying the idle time.

Aspect 9: The method, apparatus, or non-transitory computer-readable medium of any of aspects 1 through 8, where the first set of memory cells include TLCs, and the second set of memory cells include QLCs.

It should be noted that the described techniques include possible implementations, and that the operations and the steps may be rearranged or otherwise modified and that other implementations are possible. Further, portions from two or more of the methods may be combined.

Information and signals described herein may be represented using any of a variety of different technologies and techniques. For example, data, instructions, commands, information, signals, bits, symbols, and chips that may be referenced throughout the description may be represented by voltages, currents, electromagnetic waves, magnetic fields or particles, optical fields or particles, or any combination thereof. Some drawings may illustrate signals as a single signal; however, the signal may represent a bus of signals, where the bus may have a variety of bit widths.

The terms “electronic communication,” “conductive contact,” “connected,” and “coupled” may refer to a relationship between components that supports the flow of signals between the components. Components are considered in electronic communication with (or in conductive contact with or connected with or coupled with) one another if there is any conductive path between the components that can, at any time, support the flow of signals between the components. At any given time, the conductive path between components that are in electronic communication with each other (or in conductive contact with or connected with or coupled with) may be an open circuit or a closed circuit based on the operation of the device that includes the connected components. The conductive path between connected components may be a direct conductive path between the components or the conductive path between connected components may be an indirect conductive path that may include intermediate components, such as switches, transistors, or other components. In some examples, the flow of signals between the connected components may be interrupted for a time, for example, using one or more intermediate components such as switches or transistors.

The term “coupling” refers to a condition of moving from an open-circuit relationship between components in which signals are not presently capable of being communicated between the components over a conductive path to a closed-circuit relationship between components in which signals are capable of being communicated between components over the conductive path. If a component, such as a controller, couples other components together, the component initiates a change that allows signals to flow between the other components over a conductive path that previously did not permit signals to flow.

The term “isolated” refers to a relationship between components in which signals are not presently capable of flowing between the components. Components are isolated from each other if there is an open circuit between them. For example, two components separated by a switch that is positioned between the components are isolated from each other if the switch is open. If a controller isolates two components, the controller affects a change that prevents signals from flowing between the components using a conductive path that previously permitted signals to flow.

The terms “if,” “when,” “based on,” or “based at least in part on” may be used interchangeably. In some examples, if the terms “if” “when,” “based on,” or “based at least in part on” are used to describe a conditional action, a conditional process, or connection between portions of a process, the terms may be interchangeable.

The term “in response to” may refer to one condition or action occurring at least partially, if not fully, as a result of a previous condition or action. For example, a first condition or action may be performed, and second condition or action may at least partially occur as a result of the previous condition or action occurring (whether directly after or after one or more other intermediate conditions or actions occurring after the first condition or action).

Additionally, the terms “directly in response to” or “in direct response to” may refer to one condition or action occurring as a direct result of a previous condition or action. In some examples, a first condition or action may be performed, and second condition or action may occur directly as a result of the previous condition or action occurring independent of whether other conditions or actions occur. In some examples, a first condition or action may be performed, and second condition or action may occur directly as a result of the previous condition or action occurring, such that no other intermediate conditions or actions occur between the earlier condition or action and the second condition or action, or a limited quantity of one or more intermediate steps or actions occur between the earlier condition or action and the second condition or action. Any condition or action described herein as being performed “based on,” “based at least in part on,” or “in response to” some other step, action, event, or condition may additionally, or alternatively (e.g., in an alternative example), be performed “in direct response to” or “directly in response to” such other condition or action unless otherwise specified.

The devices discussed herein, including a memory array, may be formed on a semiconductor substrate, such as silicon, germanium, silicon-germanium alloy, gallium arsenide, gallium nitride, etc. In some examples, the substrate is a semiconductor wafer. In some other examples, the substrate may be a silicon-on-insulator (SOI) substrate, such as silicon-on-glass (SOG) or silicon-on-sapphire (SOP), or epitaxial layers of semiconductor materials on another substrate. The conductivity of the substrate, or sub-regions of the substrate, may be controlled through doping using various chemical species including, but not limited to, phosphorous, boron, or arsenic. Doping may be performed during the initial formation or growth of the substrate, by ion-implantation, or by any other doping means.

A switching component or a transistor discussed herein may represent a field-effect transistor (FET) and comprise a three terminal device including a source, drain, and gate. The terminals may be connected to other electronic elements through conductive materials, e.g., metals. The source and drain may be conductive and may comprise a heavily-doped, e.g., degenerate, semiconductor region. The source and drain may be separated by a lightly-doped semiconductor region or channel. If the channel is n-type (i.e., majority carriers are electrons), then the FET may be referred to as an n-type FET. If the channel is p-type (i.e., majority carriers are holes), then the FET may be referred to as a p-type FET. The channel may be capped by an insulating gate oxide. The channel conductivity may be controlled by applying a voltage to the gate. For example, applying a positive voltage or negative voltage to an n-type FET or a p-type FET, respectively, may result in the channel becoming conductive. A transistor may be “on” or “activated” if a voltage greater than or equal to the transistor's threshold voltage is applied to the transistor gate. The transistor may be “off” or “deactivated” if a voltage less than the transistor's threshold voltage is applied to the transistor gate.

The description set forth herein, in connection with the appended drawings, describes example configurations and does not represent all the examples that may be implemented or that are within the scope of the claims. The term “exemplary” used herein means “serving as an example, instance, or illustration” and not “preferred” or “advantageous over other examples.” The detailed description includes specific details to provide an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Further, various components of the same type may be distinguished by following the reference label by a hyphen and a second label that distinguishes among the similar components. If just the first reference label is used in the specification, the description is applicable to any one of the similar components having the same first reference label irrespective of the second reference label.

The functions described herein may be implemented in hardware, software executed by a processor, firmware, or any combination thereof. If implemented in software executed by a processor, the functions may be stored on or transmitted over, as one or more instructions or code, a computer-readable medium. Other examples and implementations are within the scope of the disclosure and appended claims. For example, due to the nature of software, the described functions can be implemented using software executed by a processor, hardware, firmware, hardwiring, or combinations of any of these. Features implementing functions may also be physically located at various positions, including being distributed such that portions of functions are implemented at different physical locations.

For example, the various illustrative blocks and components described in connection with the disclosure herein may be implemented or performed with a general-purpose processor, a DSP, an ASIC, an FPGA or other programmable logic device, discrete gate or transistor logic, discrete hardware components, or any combination thereof designed to perform the functions described herein. A general-purpose processor may be a microprocessor, but in the alternative, the processor may be any processor, controller, microcontroller, or state machine. A processor may be implemented as a combination of computing devices (e.g., a combination of a DSP and a microprocessor, multiple microprocessors, one or more microprocessors in conjunction with a DSP core, or any other such configuration).

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

Computer-readable media includes both non-transitory computer storage media and communication media including any medium that facilitates transfer of a computer program from one place to another. A non-transitory storage medium may be any available medium that can be accessed by a general purpose or special purpose computer. By way of example, and not limitation, non-transitory computer-readable media can comprise RAM, ROM, electrically erasable programmable read-only memory (EEPROM), compact disk (CD) ROM or other optical disk storage, magnetic disk storage or other magnetic storage devices, or any other non-transitory medium that can be used to carry or store desired program code means in the form of instructions or data structures and that can be accessed by a general-purpose or special-purpose computer, or a general-purpose or special-purpose processor. Also, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of medium. Disk and disc, as used herein, include CD, laser disc, optical disc, digital versatile disc (DVD), floppy disk, and Blu-ray disc, where disks usually reproduce data magnetically, while discs reproduce data optically with lasers. Combinations of these are also included within the scope of computer-readable media.

The description herein is provided to enable a person skilled in the art to make or use the disclosure. Various modifications to the disclosure will be apparent to those skilled in the art, and the generic principles defined herein may be applied to other variations without departing from the scope of the disclosure. Thus, the disclosure is not limited to the examples and designs described herein but is to be accorded the broadest scope consistent with the principles and novel features disclosed herein.

What is claimed is:

1. An apparatus, comprising:
a controller associated with a memory device, wherein the controller is configured to cause the apparatus to:
receive a write command to write data to a memory system;
write the data to a first set of memory cells of the memory system using a first write operation based at least in part on receiving the write command, wherein the first set of memory cells store three or fewer bits of information in a single memory cell;
identify whether to transfer the data to a second set of memory cells that store more bits of information in a single memory cell than the first set of memory cells based at least in part on one or more parameters associated with the data; and
transfer the data to the second set of memory cells of the memory system using a second write operation based at least in part on identifying that the data is to be transferred.

2. The apparatus of claim 1, wherein the controller is further configured to cause the apparatus to:
write, while writing the data to the first set of memory cells, a temperature of the data during the first write operation, the one or more parameters associated with the data comprises the temperature, wherein transferring the data to the second set of memory cells of the memory system is based at least in part on the temperature of the data satisfying a temperature threshold.

3. The apparatus of claim 1, wherein the controller is further configured to cause the apparatus to:
receive, as part of the write command, a flag indicating that the data is a first type, the one or more parameters associated with the data comprising the flag, wherein transferring the data to the second set of memory cells of the memory system is based at least in part on receiving the flag indicating that the data is the first type.

4. The apparatus of claim 1, wherein the controller is further configured to cause the apparatus to:
identify that the data is associated with a first region of the memory system, wherein the first region of the memory system stores a first type of data and the one or more parameters associated with the data comprises an indication of the first region, wherein transferring the data to the second set of memory cells of the memory system is based at least in part on writing the data to the first region associated with the first type of data.

5. The apparatus of claim 1, wherein the controller is further configured to cause the apparatus to:
receive an indication of a duration of time associated with performing a start-up procedure, the one or more parameters associated with the data comprising the indication of the duration; and
identify, during the start-up procedure, that the data is accessed after the duration of time indicated, wherein transferring the data to the second set of memory cells of the memory system is based at least in part on identifying that the data is accessed after the duration of time indicated.

6. The apparatus of claim 1, wherein the controller is further configured to cause the apparatus to:
identify that the data is stored to a first region of the memory system that is different than a second region associated with performing a start-up procedure, wherein, transferring the data to the second set of memory cells of the memory system is based at least in part on identifying that the data is stored to the first region.

7. The apparatus of claim 1, wherein the controller is further configured to cause the apparatus to:
receive an indication of a data storage configuration of the memory system, wherein the data storage configuration indicates a data quantity threshold for storing a second type of data to the memory system, the one or more parameters associated with the data comprising the data storage configuration; and
identify that a quantity of data stored to the memory system is of the second type and that the quantity of data stored satisfies the data quantity threshold, wherein transferring the data to the second set of memory cells of the memory system is based at least in part on identifying that the data quantity threshold is satisfied.

8. The apparatus of claim 1, wherein the controller is further configured to cause the apparatus to:
identify an idle time associated with inactivity of the memory system, wherein transferring the data to the second set of memory cells of the memory system is based at least in part on identifying the idle time.

9. The apparatus of claim 1, wherein the first set of memory cells comprise triple-level cells and the second set of memory cells comprise quad-level cells.

10. A non-transitory computer-readable medium storing code, the code comprising instructions executable by a processor to:
receive a write command to write data to a memory system;
write the data to a first set of memory cells of the memory system using a first write operation based at least in part on receiving the write command, wherein the first set of memory cells store three or fewer bits of information in a single memory cell;
identify whether to transfer the data to a second set of memory cells that store more bits of information in a single memory cell than the first set of memory cells based at least in part on one or more parameters associated with the data; and
transfer the data to the second set of memory cells of the memory system using a second write operation based at least in part on identifying that the data is to be transferred.

11. The non-transitory computer-readable medium of claim 10, wherein the instructions are further executable by the processor to:
write, while writing the data to the first set of memory cells, a temperature of the data during the first write operation, the one or more parameters associated with the data comprises the temperature, wherein transferring the data to the second set of memory cells of the memory system is based at least in part on the temperature of the data satisfying a temperature threshold.

12. The non-transitory computer-readable medium of claim 10, wherein the instructions are further executable by the processor to:
receive, as part of the write command, a flag indicating that the data is a first type, the one or more parameters associated with the data comprising the flag, wherein transferring the data to the second set of memory cells of the memory system is based at least in part on receiving the flag indicating that the data is the first type.

13. The non-transitory computer-readable medium of claim 10, wherein the instructions are further executable by the processor to:
identify that the data is associated with a first region of the memory system, wherein the first region of the memory system stores a first type of data and the one or more parameters associated with the data comprises an indication of the first region, wherein transferring the data to the second set of memory cells of the memory system is based at least in part on writing the data to the first region associated with the first type of data.

14. The non-transitory computer-readable medium of claim 10, wherein the instructions are further executable by the processor to:
receive an indication of a duration of time associated with performing a start-up procedure, the one or more parameters associated with the data comprising the indication of the duration; and
identify, during the start-up procedure, that the data is accessed after the duration of time indicated, wherein transferring the data to the second set of memory cells of the memory system is based at least in part on identifying that the data is accessed after the duration of time indicated.

15. The non-transitory computer-readable medium of claim 10, wherein the instructions are further executable by the processor to:
identify that the data is stored to a first region of the memory system that is different than a second region associated with performing a start-up procedure, wherein, transferring the data to the second set of memory cells of the memory system is based at least in part on identifying that the data is stored to the first region.

16. The non-transitory computer-readable medium of claim 10, wherein the instructions are further executable by the processor to:
receive an indication of a data storage configuration of the memory system, wherein the data storage configuration indicates a data quantity threshold for storing a second type of data to the memory system, the one or more parameters associated with the data comprising the data storage configuration; and
identify that a quantity of data stored to the memory system is of the second type and that the quantity of data stored satisfies the data quantity threshold, wherein transferring the data to the second set of memory cells of the memory system is based at least in part on identifying that the data quantity threshold is satisfied.

17. The non-transitory computer-readable medium of claim 10, wherein the instructions are further executable by the processor to:
identify an idle time associated with inactivity of the memory system, wherein transferring the data to the second set of memory cells of the memory system is based at least in part on identifying the idle time.

18. The non-transitory computer-readable medium of claim 10, wherein the first set of memory cells comprise triple-level cells and the second set of memory cells comprise quad-level cells.

19. A method, comprising:
receiving a write command to write data to a memory system;
writing the data to a first set of memory cells of the memory system using a first write operation based at least in part on receiving the write command, wherein the first set of memory cells store three or fewer bits of information in a single memory cell;
identifying whether to transfer the data to a second set of memory cells that store more bits of information in a single memory cell than the first set of memory cells based at least in part on one or more parameters associated with the data; and
transferring the data to the second set of memory cells of the memory system using a second write operation based at least in part on identifying that the data is to be transferred.

20. The method of claim 19, further comprising:
writing, while writing the data to the first set of memory cells, a temperature of the data during the first write operation, the one or more parameters associated with the data comprises the temperature, wherein transferring the data to the second set of memory cells of the memory system is based at least in part on the temperature of the data satisfying a temperature threshold.
